(19) United States
(12) Patent Application Publication
(10) Pub. No.: US 2016/0118322 A1
(43) Pub. Date: Apr. 28, 2016

(54) LAMINATED SUBSTRATE AND METHOD FOR MANUFACTURING LAMINATED SUBSTRATE

(71) Applicant: FUJITSU LIMITED, Kawasaki-shi (JP)

(72) Inventors: Takashi KANDA, Kawasaki (JP); Shunji BABA, Yokohama (JP)

(73) Assignee: FUJITSU LIMITED, KAWASAKI (JP)

(21) Appl. No.: 14/837,131

(22) Filed: Aug. 27, 2015

(30) Foreign Application Priority Data
Oct. 27, 2014 (JP) 2014-218136

(51) Int. Cl. H01L 23/498; H01L 21/48; H05K 1/11

(52) U.S. Cl. CPC H01L 23/49822; H01L 23/49838; H05K 1/111; H01L 23/49827; H01L 21/4857; H01L 21/4853

(57) ABSTRACT

A laminated substrate includes: a core portion; a first wiring portion configured to be stacked on the core portion and to include a first exposed surface formed by exposing at least part of a surface of the first wiring portion; and a second wiring portion configured to be stacked on the first wiring portion, to include a second exposed surface formed by exposing at least part of a surface of the second wiring portion, and to have higher wiring density of conductor than the first wiring portion has, wherein the first exposed surface and the second exposed surface are provided respectively with a first pad and a second pad which are to be connected to electrodes of one semiconductor chip to be mounted on both the first exposed surface and the second exposed surface.

### CROSS-REFERENCE TO RELATED APPLICATION

This application is based upon and claims the benefit of priority of the prior Japanese Patent Application No. 2014-218136, filed on Oct. 27, 2014, the entire contents of which are incorporated herein by reference.

### FIELD

The embodiments discussed herein are related to, for example, a laminated substrate and a method for manufacturing the laminated substrate.

### BACKGROUND

With an increase in speed and capacity of electronic devices, there is increasing demand for high-density packaging technique which achieves high-density connection among logic chips and memory chips. As one of this type of high-density packaging technique, there is known a 2.5-dimensional packaging structure in which a silicon interposer manufactured by a silicon process is mounted on a core substrate, and logic chips and memory chips are planarly mounted on the silicon interposer. In the 2.5-dimensional packaging structure, the memory chip is sometimes mounted on the silicon interposer via a through-silicon via (TSV). International Publication Pamphlet No. WO 2009/141927, Japanese Laid-open Patent Publication No. 11-317582, and Japanese Laid-open Patent Publication No. 2000-165007 may be given as examples of the related art.

### SUMMARY

In accordance with an aspect of the embodiments, a laminated substrate includes: a core portion; a first wiring portion configured to be stacked on the core portion and to include a first exposed surface formed by exposing at least part of a surface of the first wiring portion; and a second wiring portion configured to be stacked on the first wiring portion, to include a second exposed surface formed by exposing at least part of a surface of the second wiring portion, and to have higher wiring density of conductor than the first wiring portion has, wherein the first exposed surface and the second exposed surface are provided respectively with a first pad and a second pad which are to be connected to electrodes of one semiconductor chip to be mounted on both the first exposed surface and the second exposed surface.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

These and/or other aspects and advantages will become apparent and more readily appreciated from the following description of the embodiments, taken in conjunction with the accompanying drawing of which:

FIG. 1 is a view illustrating a plan view of a semiconductor package in embodiment 1;

FIG. 2 is a view illustrating a cross-sectional structure of the semiconductor package in embodiment 1;

FIG. 3 is a view illustrating a core portion, a first wiring portion, and second wiring portions in embodiment 1;

FIG. 4 is a view illustrating adhesive sheets in embodiment 1;

FIG. 5 is a view illustrating temporarily bonding of a first adhesive sheet and a second adhesive sheet in embodiment 1;

FIG. 6 is a view illustrating filling of a conductive paste into through holes of the first adhesive sheet and the second adhesive sheet in embodiment 1;

FIG. 7 is a view illustrating stacking of the first wiring portion and the second wiring portion in embodiment 1;

FIG. 8 is a cross-sectional view of a partially-high-density laminated substrate in embodiment 2; and

FIG. 9 is a cross-sectional view of a partially-high-density laminated substrate in embodiment 3.

### DESCRIPTION OF EMBODIMENTS

Hereafter, embodiments of this disclosure are described with reference to the drawings.

### Embodiment 1

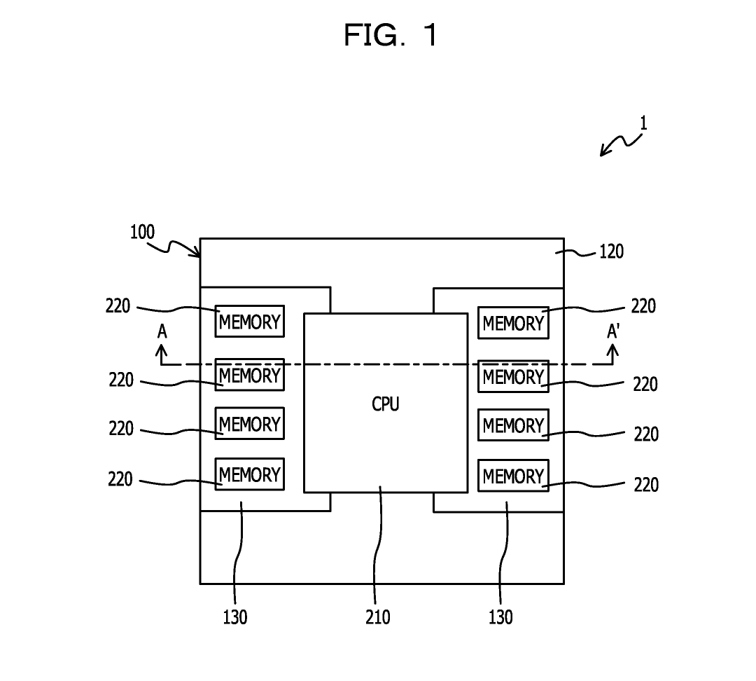

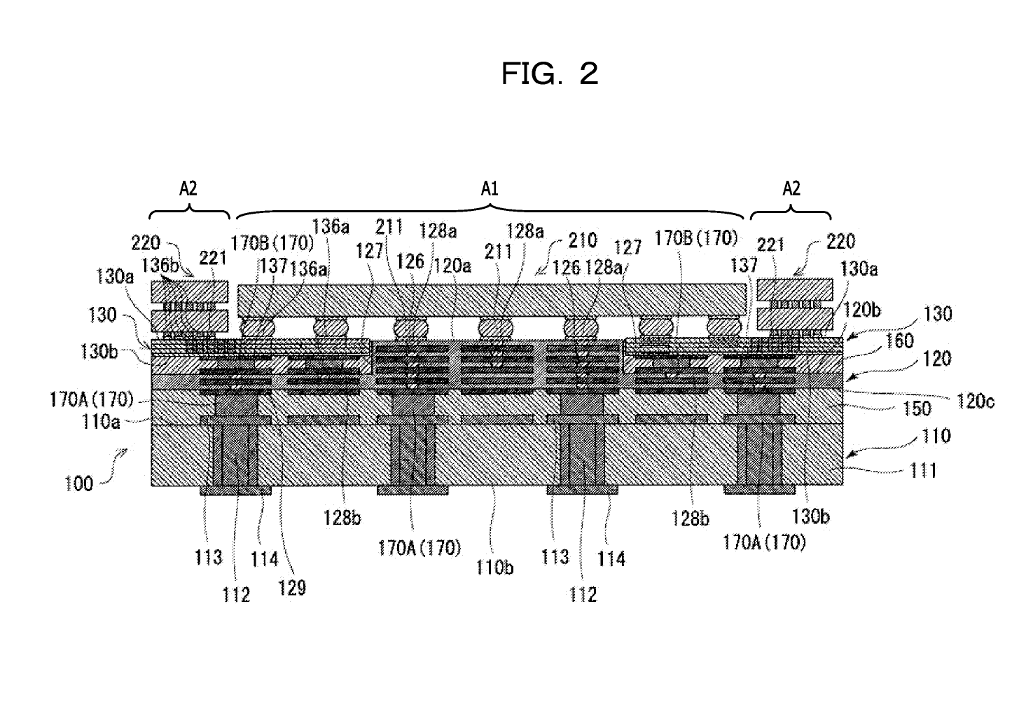

FIG. 1 is a view illustrating a plan view of a semiconductor package 1 in embodiment 1. FIG. 2 is a view illustrating a cross-sectional structure of the semiconductor package 1 in embodiment 1. The semiconductor package 1 includes a partially-high-density laminated substrate 100, a logic chip 210, and multiple memory chips 220, the logic chip 210, and the memory chips 220 being mounted on the partially-high-density laminated substrate 100. In this description, the logic chip 210 and the memory chips 220 are collectively referred to as semiconductor chips.

In the example depicted in FIG. 1, the logic chip 210 is arranged at the center of an upper surface 100a of the partially-high-density laminated substrate 100 and the multiple memory chips 220 are arranged to surround the logic chip 210.

FIG. 2 schematically depicts a cross section taken along the line A-A′ in FIG. 1 as viewed in the direction of the arrows. The partially-high-density laminated substrate 100 has a core portion (also referred to as core substrate) 110, a first wiring portion 120 stacked on the core portion 110, second wiring portions 130 stacked on the first wiring portion 120, and the like.

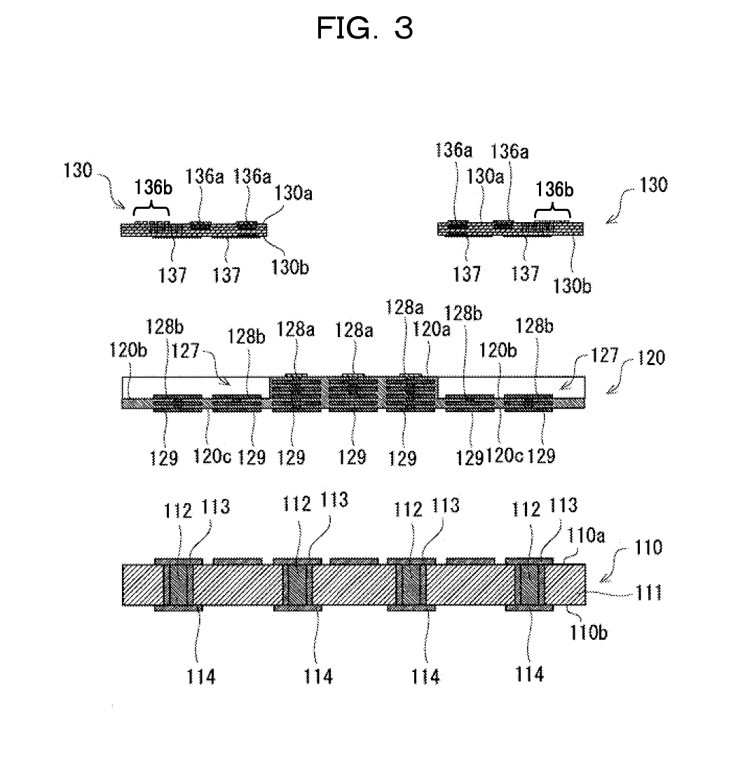

FIG. 3 is a view illustrating the core portion 110 of the partially-high-density laminated substrate 100 in embodiment 1. The core portion 110 is a printed wiring board having a core board 111 and through hole vias 112 penetrating the core board 111 in a thickness direction. Lands 113 and 114 are formed on an upper surface 110a and a lower surface 110b of the core portion 110. The lands 113 formed on the upper surface 110a of the core portion 110 and the lands 114 formed on the lower surface 110b of the core portion 110 are electrically connected to one another via the through hole vias 112. For example, a glass epoxy resin substrate may be used as the core board 111 in the core portion 110. Moreover, the through hole vias 112 are formed by making through holes in the core board 111 by laser processing, drilling, punching, or the like and plating inner surfaces of the through holes with metal. The lands 113 and 114 are formed around the through hole vias 112 on the upper surface 110a and the lower surface 110b of the core portion 110, and the lands 113 on the upper surface 110a and the lands 114 on the lower surface 110b are electrically connected to one another via the through hole vias 112.

FIG. 3 is a view illustrating the first wiring portion 120 and the second wiring portions 130 of the partially-high-density laminated substrate 100 in embodiment 1. The first wiring portion 120 and the second wiring portions 130 are each multiple wiring layers fabricated by a publicly-known build-up method. The first wiring portion 120 has the same shape and size as the core portion 110 to cover the entire surface of the core portion 110, and is formed by stacking multiple wiring layers. Interlayer connection between wiring patterns in the respective wiring layers of the first wiring portion 120 is achieved by vias 126.

An upper surface of the first wiring portion 120 includes an exposed upper surface 120a located in a center portion of the first wiring portion 120 in a planar direction and covered upper surfaces 120b located in end portions of the first wiring portion 120 and covered with the second wiring portions 130 stacked on the covered upper surfaces 120b. In the center portion of the first wiring portion 120, that is a region corresponding to the exposed upper surface 120a, the structure of the wiring layers is a five-layer structure. Meanwhile, in the end portions of the first wiring portion 120, that is regions corresponding to the covered upper surfaces 120b, the structure of the wiring layers is a two-layer structure. Recess portions 127 are formed in the end portions of the first wiring portion 120 by setting the number of stacked wiring layers in the end portions of the first wiring portion 120 smaller than that in the center portion of the first wiring portion 120. The recess portions 127 of the first wiring portion 120 are recess portions which house the second wiring portions 130 as described in detail later.

Pads 128a which are electrodes to be soldered to bumps (electrodes) 211 formed in the logic chip 210 are formed on the exposed upper surface 120a of the first wiring portion 120. Moreover, pads 128b which are electrodes for external connection are formed on the covered upper surfaces 120b (also corresponding to bottom surfaces of the recess portions 127) of the first wiring portion 120. Furthermore, pads 129 which are electrodes for external connection are formed on a lower surface 120c of the first wiring portion 120. The pads 129 in the first wiring portion 120 are formed at such positions that the pads 129 face (vertically overlap) the lands 113 of the core portion 110 when the first wiring portion 120 is stacked on the core portion 110.

Meanwhile, the second wiring portions 130 are each formed by stacking multiple wiring layers, and interlayer connection between wiring patterns in the wiring layers stacked one on top of another is achieved by vias. The second wiring portions 130 are housed (accommodated) in the recess portions 127 formed in the first wiring portion 120. Pads 136a which are electrodes to be soldered to the bumps 211 formed on the bottom surface of the logic chip 210 are formed in regions of upper surfaces 130a of the second wiring portions 130 which are close to the exposed upper surface 120a of the first wiring portion 120. Moreover, pads 136b which are electrodes to be soldered to bumps 221 formed on bottom surfaces of the memory chips 220 are formed in regions of the upper surfaces 130a of the second wiring portions 130 which are outside the regions where the pads 136a are arranged. Furthermore, pads 137 which are electrodes for external connection are formed on lower surfaces 130b of the second wiring portions 130.

In the partially-high-density laminated substrate 100 in embodiment 1, the wiring density of the wiring patterns (conductor) in the wiring layers of the second wiring portions 130 is higher than the wiring density of the wiring patterns (conductor) in the wiring layers of the first wiring portion 120. In other words, in the second wiring portions 130, wiring which is finer and higher in density than wiring in the first wiring portion 120 is achieved. For example, in the wiring patterns in the wiring layers of the first wiring portion 120, line (line width L)/space (distance S between lines) is set to about 15 μm/15 μm. Meanwhile, in the wiring patterns in the wiring layers of the second wiring portions 130, the line/space (L/S) is set to about 2 μm/2 μm. Note that the aforementioned wiring densities are given as examples. Moreover, in the partially-high-density laminated substrate 100, the wiring density of the wiring patterns (conductor) in the wiring layers of the first wiring portion 120 is higher than the wiring density of the wiring patterns (conductor) in the wiring layers of the core portion 110.

Moreover, pad intervals of the pads 128a in the first wiring portion 120 and the pads 136a in the second wiring portions 130 are equal to intervals of the bumps 211 in the logic chip 210. Due to this, the logic chip 210 which is one semiconductor chip may be mounted on both the exposed upper surface 120a of the first wiring portion 120 and the upper surfaces 130a of the second wiring portions 130. For example, the pad intervals of the exposed upper surface pads 128a and the upper surface pads 136a and the intervals of the bumps 211 in the logic chip 210 may be set to about 150 μm. Hereafter, the regions of the upper surfaces 130a of the second wiring portions 130 where the pads 136a are formed and the exposed upper surface 120a of the first wiring portion 120 are collectively referred to as “logic chip mounting region A1”. Moreover, the regions of the upper surfaces 130a of the second wiring portions 130 where the pads 136b are formed are referred to as “memory chip mounting regions A2”.

Furthermore, the intervals of the pads 136b in the memory chip mounting regions A2 of the second wiring portions 130 are smaller than the intervals of the pads 128a and the pads 136a in the logic chip mounting region A1, and are equal to the intervals of the bumps 221 of the memory chips 220. In embodiment 1, the intervals of the pads 136b in the memory chip mounting regions A2 are set to, for example, about 40 μm. In the mounting of the memory chips 220, the bumps 221 formed on the bottom surfaces of the memory chips 220 are soldered to the pads 136b formed in the memory chip mounting regions A2 of the second wiring portions 130. The memory chips 220 are thereby mounted face down on the partially-high-density laminated substrate 100 like the logic chip 210.

The first wiring portion 120 and the second wiring portions 130 may be fabricated by a publicly-known build-up method. An example of a method of manufacturing the first wiring portion 120 and the second wiring portions 130 is described. A prepreg obtained by impregnating a nonwoven fabric of aramid fiber with an epoxy resin is prepared, and through holes are formed in the prepreg by laser processing or the like. Then, the through holes of the prepreg are filled with a conductive paste, and the prepreg is laminated with copper foil by laminating pressing. A substrate whose both surfaces are covered with the copper foil and which has vias in inner layers are thereby obtained. Next, the surface copper foil is patterned by photo-etching or the like to obtain a double-sided substrate in which wiring patterns are formed. Then, the double-sided substrate is laminated with copper foil and a prepreg having through holes filled with the conductive paste, and thereafter the surface copper foil is patterned. The first wiring portion 120 and the second wiring portions 130 may be fabricated by repeating lamination of the wiring layers a predetermined number of times as described above.

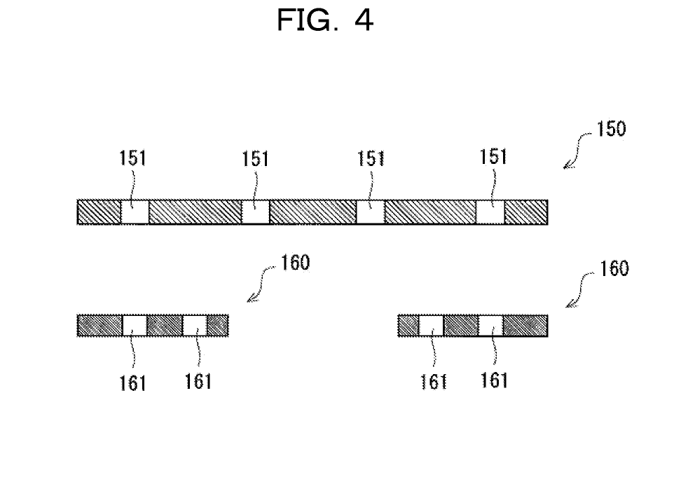

Hereafter, steps of manufacturing the partially-high-density laminated substrate 100 and the semiconductor package 1 are described. The partially-high-density laminated substrate 100 is manufactured such that, as depicted in FIG. 3, the core portion 110, the first wiring portion 120, and the second wiring portions 130 are independently fabricated and are bonded to one another by adhesive sheets. FIG. 4 is a view illustrating the adhesive sheets in embodiment 1. Reference numeral 150 in FIG. 4 denotes a first adhesive sheet for bonding the first wiring portion 120 to the core portion 110. Moreover, reference numeral 160 denotes second adhesive sheets for bonding the second wiring portions 130 to the first wiring portion 120. The first adhesive sheet 150 and the second adhesive sheets 160 are, for example, b-staged glass epoxy prepregs obtained by impregnating glass fiber with an epoxy resin.

The first adhesive sheet 150 has the same size as the core portion 110 and the first wiring portion 120, and through holes 151 penetrating the first adhesive sheet 150 in a thickness direction are provided in the first adhesive sheet 150 at predetermined positions. Moreover, the second adhesive sheets 160 have the same size as the recess portions 127 of the first wiring portion 120 and the second wiring portions 130, and through holes 161 penetrating the second adhesive sheets 160 in a thickness direction are provided in the second adhesive sheets 160 at predetermined positions. The through holes 151 of the first adhesive sheet 150 and the through holes 161 of the second adhesive sheets 160 may be formed by, for example, drilling or the like. The through holes 151 and 161 are filled with a conductive paste (conductive adhesive) when the core portion 110 and the first wiring portion 120 are bonded to each other by the first adhesive sheet 150 and when the first wiring portion 120 and the second wiring portions 130 are bonded to one another by the second adhesive sheets 160.

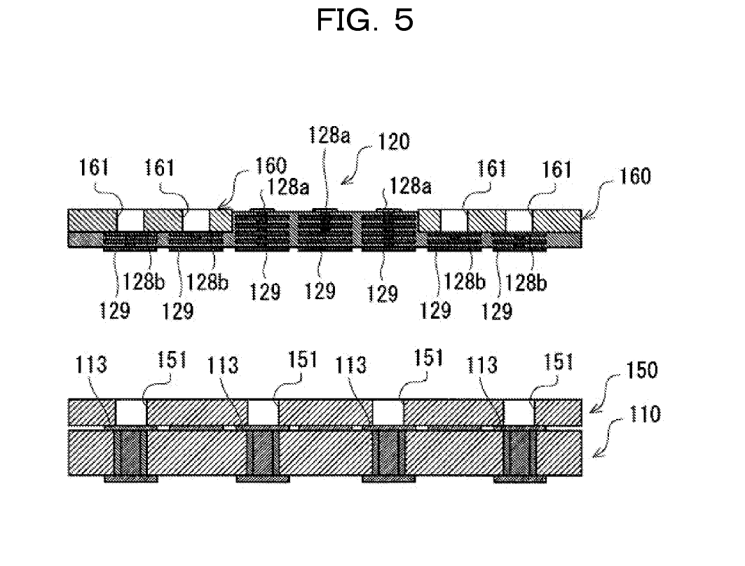

FIG. 5 is a view illustrating temporality bonding of the first adhesive sheet 150 and the second adhesive sheets 160. In embodiment 1, the first adhesive sheet 150 is aligned with the upper surface 110a of the core portion 110 and placed thereon while being preheated. Moreover, the second adhesive sheets 160 are aligned with the recess portions 127 of the first wiring portion 120 and placed thereon while being preheated. The preheating temperature is set to a temperature lower than the curing temperature of the epoxy resin (for example, about 150° C.) and equal to or higher than the softening temperature of the epoxy resin. In embodiment 1, the preheating temperature is set to, for example, about 80° C. The first adhesive sheet 150 and the second adhesive sheets 160 are softened by being preheated. Aligning the first adhesive sheet 150 while softening the first adhesive sheet 150 enables accurate temporarily attachment (temporarily fixation) of the first adhesive sheet 150 to the core portion 110 at a correct position. Moreover, aligning the second adhesive sheets 160 while softening the second adhesive sheets 160 enables accurate temporarily attachment (temporarily fixation) of the second adhesive sheets 160 to the recess portions 127 of the first wiring portion 120 at correct positions.

In embodiment 1, the positions of the lands 113 of the core portion 110 and the through holes 151 of the first adhesive sheet 150 are associated with one another such that the lands 113 and the through holes 151 are arranged to face one another (vertically overlap one another) in the state where the first adhesive sheet 150 is temporarily attached to the core portion 110. Moreover, the positions of the pads 128b of the first wiring portion 120 and the through holes 161 of the second adhesive sheets 160 are associated with one another such that the pads 128b and the through holes 161 are arranged to face one another in the state where the second adhesive sheets 160 are temporarily attached to the first wiring portion 120.

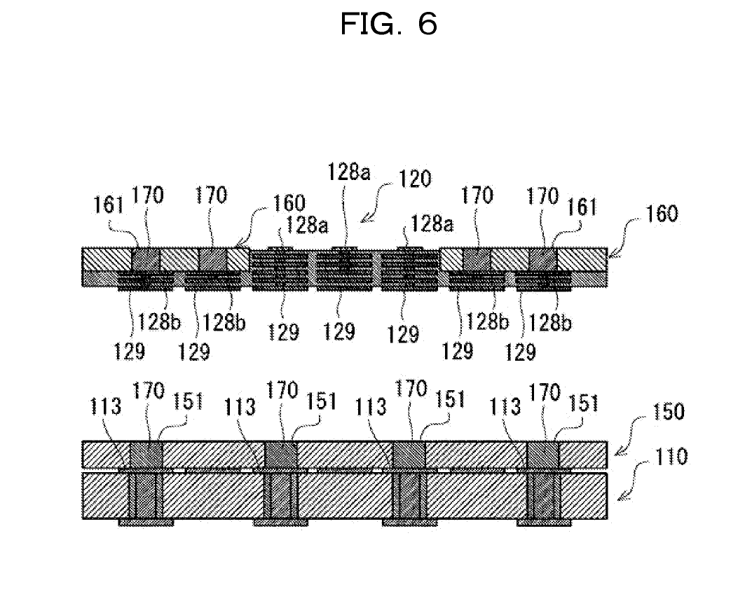

Next, as depicted in FIG. 6, a conductive paste 170 is filled into the through holes 151 of the first adhesive sheet 150 temporarily attached to the core portion 110. Moreover, the conductive paste 170 is filled into the through holes 161 of the second adhesive sheets 160 temporarily attached to the first wiring portion 120. The conductive paste 170 is a mixture of metal particles (conductive filler) and a resin material. For example, particles of copper, gold, silver, palladium, nickel, tin, lead, or the like may be used as the metal particles, or metal particles of two or more types of metal may be used. Moreover, for example, a thermosetting resin such as an epoxy resin is used as the resin material. However, the resin material used in the conductive paste 170 is not limited to the epoxy resin, and other resins such as a polyimide resin may be used. Furthermore, a pressure-contact-type conductive paste or a melt-type conductive paste may be used as the conductive paste 170. In the pressure-contact-type conductive paste, conductivity is obtained by thermally curing the resin with the metal particles pressed against each other. Moreover, in the melt-type conductive paste, conductivity is obtained by applying heat and pressure to the paste so that the metal particles may be melted to form an alloy.

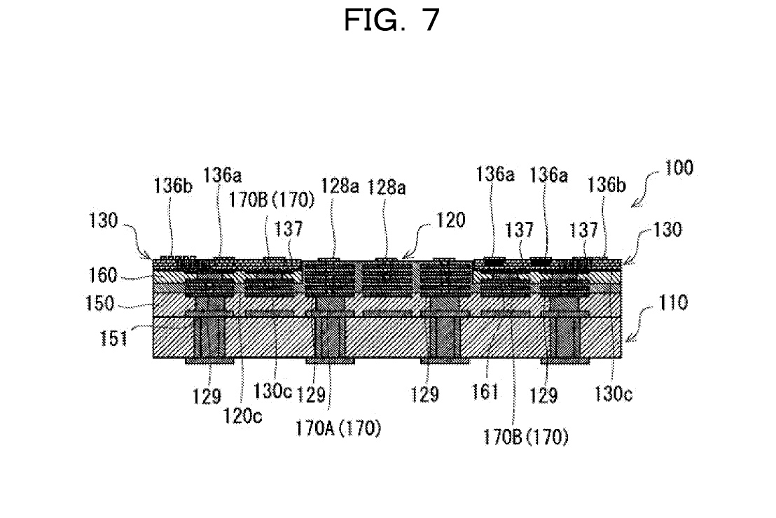

Next, as depicted in FIG. 7, the first wiring portion 120 is stacked on the core portion 110, and the second wiring portions 130 are stacked on the first wiring portion 120. In this stacking step, the first wiring portion 120 is aligned and placed on the core portion 110, and the second wiring portions 130 are aligned and placed on the first wiring portion 120. In embodiment 1, the positional relationships of the pads 129 arranged on the lower surface 120c of the first wiring portion 120 and the through holes 151 (conductive paste 170) of the first adhesive sheet 150 are associated such that the pads 129 are arranged to face the through holes 151. Moreover, the positional relationships of the pads 137 arranged on the lower surfaces 130b of the second wiring portions 130 and the through holes 161 (conductive paste 170) of the second adhesive sheets 160 are associated such that the pads 137 are arranged to face the through holes 161.

Then, in the stacking step, the first adhesive sheet 150 is interposed between the core portion 110 and the first wiring portion 120, whereas the second adhesive sheets 160 is interposed between the first wiring portion 120 and the second wiring portions 130, and in this state, hot pressing is performed in which the stacked portions and sheets are pressed in a stacking direction while being heated. The hot pressing is performed by using, for example, a vacuum pressing device. When the hot pressing using the vacuum pressing device is started, the epoxy resin in the first adhesive sheet 150 and the second adhesive sheets 160 with which the glass fiber is impregnated and the epoxy resin included in the conductive paste 170 is melted. Then, the epoxy resin is heated to the curing temperature range while the softened first adhesive sheet 150 and second adhesive sheets 160 are compressed in the stacking direction by pressing, and the epoxy resin is thereby cured. As a result, as depicted in FIG. 7, the core portion 110 and the first wiring portion 120 are bonded to each other via the first adhesive sheet 150, and the first wiring portion 120 and the second wiring portions 130 are bonded to one another via the second adhesive sheets 160. The first wiring portion 120 is thus stacked on the core portion 110, the second wiring portions 130 are stacked on the first wiring portion 120, and the partially-high-density laminated substrate 100 is completed.

In the partially-high-density laminated substrate 100, vias 170A and 170B are formed by the conductive paste 170 in which the epoxy resin is cured in the aforementioned stacking step. The vias 170A are arranged in the first adhesive sheet 150 and achieve electrical interlayer connection between the pads 129 of the first wiring portion 120 and the lands 113 of the core portion 110. Meanwhile, the vias 170B are arranged in the second adhesive sheets 160 and achieve electrical interlayer connection between the pads 137 of the second wiring portions 130 and the pads 128b of the first wiring portion 120.

Then, the logic chip 210 is mounted on the logic chip mounting region A1 of the partially-high-density laminated substrate 100 fabricated as described above, and the memory chips 220 are mounted on the memory chip mounting regions A2 of the partially-high-density laminated substrate 100. As a result, the semiconductor package 1 depicted in FIG. 2 is completed. Specifically, the logic chip 210 is mounted on the partially-high-density laminated substrate 100 by soldering the bumps 211 of the logic chip 210 to the pads 128a of the first wiring portion 120 and the pads 136a of the second wiring portions 130. Moreover, the memory chips 220 are mounted on the partially-high-density laminated substrate 100 by soldering the bumps 221 formed on the bottom surfaces of the memory chips 220 to the pads 136b formed in the memory chip mounting regions A2 of the second wiring portions 130.

As depicted in FIGS. 1 to 7, in the partially-high-density laminated substrate 100 of embodiment 1, the first wiring portion 120 is stacked on the core portion 110 such that the covered upper surfaces 120b are exposed. Then, the second wiring portions 130 whose wiring densities in the wiring layers are higher than that of the first wiring portion 120 are stacked on the first wiring portion 120 such that the upper surfaces 130a are exposed. Next, the pads 128a and 136a are provided on the covered upper surfaces 120b of the first wiring portion 120 and the upper surfaces 130a of the second wiring portions 130, and the logic chip 210 is mounted on both the first wiring portion 120 and the second wiring portions 130. According to this configuration, it is possible to form the second wiring portions 130 in portions where the logic chip 210 and the memory chips 220 are to be connected to one another, that is portions where high-density fine wiring is desirable, and to form the first wiring portion 120 whose wiring density is lower than that of the second wiring portions 130 in other portions.

As a result, the high-density fine wiring does not have to be formed over the entire substrate, and the area of the second wiring portions 130 may be reduced. Accordingly, a decrease of manufacturing yield and an increase of manufacturing cost may be suppressed. In other words, according to the partially-high-density laminated substrate 100 of embodiment 1, it is possible to suppress the decrease of manufacturing yield and the increase of manufacturing cost in the case where multiple semiconductor chips are connected to one another via fine wiring formed in a substrate. Moreover, since the second wiring portions 130 may be freely arranged in a surface of the partially-high-density laminated substrate 100, the degree of freedom in design may be increased. In the embodiment, the pads 128a formed on the covered upper surfaces 120b of the first wiring portion 120 are an example of a first pad. Meanwhile, the pads 136a formed on the upper surfaces 130a of the second wiring portions 130 are an example of a second pad.

Moreover, in embodiment 1, the core portion 110, the first wiring portion 120, and the second wiring portions 130 are independently fabricated, the core portion 110 and the first wiring portion 120 are connected via the vias 170A (conductive paste 170), and the first wiring portion 120 and the second wiring portions 130 are connected via the vias 170B (conductive paste 170). Independently fabricating the first wiring portion 120 and the second wiring portions 130 which vary in the wiring density of the conductor in the wiring layers as described above may improve the manufacturing yield. Moreover, it is possible to perform a quality check on the independently-fabricated core portion 110, first wiring portion 120, and second wiring portions 130 and manufacture the partially-high-density laminated substrate 100 by using only good products. Accordingly, when there is a defect in any of the core portion 110, the first wiring portion 120, and the second wiring portions 130, it is possible to replace the portion with the defect and further improve the manufacturing yield.

Furthermore, in embodiment 1, the core portion 110, the first wiring portion 120, and the second wiring portions 130 are bonded to one another with the first adhesive sheet 150 and the second adhesive sheets 160 being temporarily fixed to the core portion 110 and the first wiring portion 120. Accordingly, the first wiring portion 120 may be accurately aligned with the core portion 110 and stacked thereon. Moreover, the second wiring portions 130 may be accurately aligned with the first wiring portion 120 and stacked thereon.

Moreover, in the partially-high-density laminated substrate 100, the second wiring portions 130 are stacked on the first wiring portion 120 in such a manner that the second wiring portions 130 are housed in the recess portions 127 provided in the first wiring portion 120. Specifically, the second wiring portions 130 are stacked on the first wiring portion 120 in such a manner that the second wiring portions 130 are embedded (placed) inside the recess portions 127 provided in the first wiring portion 120. According to this configuration, it is possible to suppress formation of a step between the exposed upper surface 120a of the first wiring portion 120 and each of the upper surfaces 130a of the second wiring portions 130. In other words, the logic chip mounting region A1 in the partially-high-density laminated substrate 100 may be formed to be flat. Accordingly, the mounting of the logic chip 210 may be performed by using a normal chip mounter. Note that, although the second wiring portions 130 are entirely embedded (placed) inside the recess portions 127 provided in the first wiring portion 120 in embodiment 1, the second wiring portions 130 may be partially embedded in the recess portions 127.

### Embodiment 2

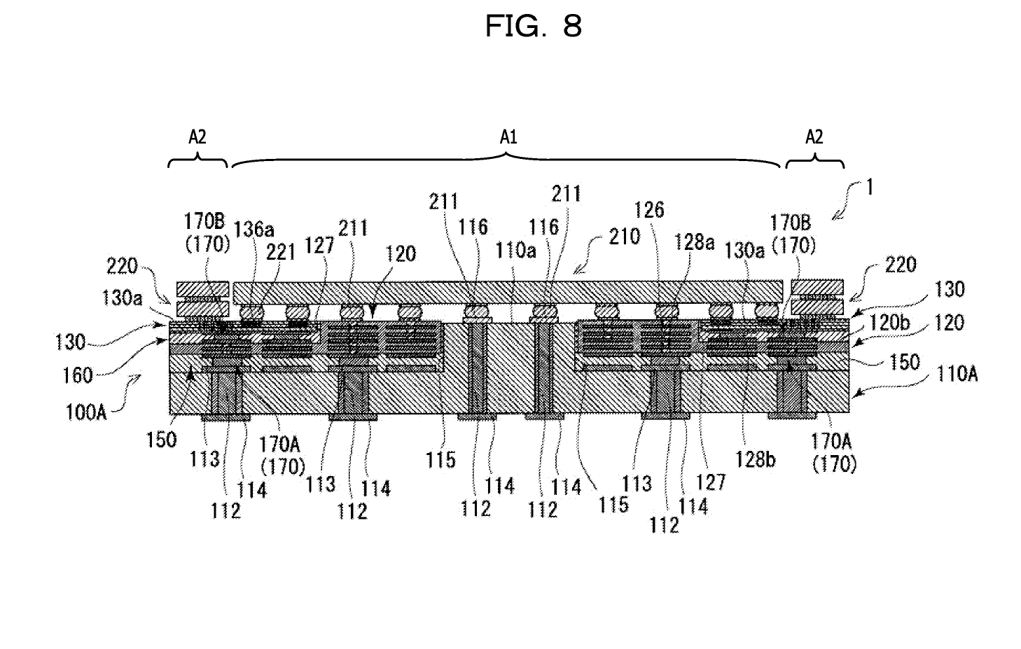

Next, a partially-high-density laminated substrate 100A in embodiment 2 is described. FIG. 8 is a cross-sectional view of the partially-high-density laminated substrate 100A in embodiment 2. In this section, differences from the partially-high-density laminated substrate 100 in embodiment 1 are mainly described.

In the partially-high-density laminated substrate 100A in embodiment 2, the structure of a core portion 110A is different from the structure of the core portion 110 in embodiment 1. The core portion 110A in embodiment 2 is provided with recess portions 115 which house first wiring portions 120. In embodiment 2, the recess portions 115 are provided in two portions of the core portion 110A, and the first wiring portions 120 are stacked on the core portion 110A in such a manner that the first wiring portions 120 is embedded (placed) inside the recess portions 115.

Moreover, lands 116 are formed in a center portion of an upper surface 110a of the core portion 110A, and the lands 116 and bumps 211 formed in a bottom portion of a logic chip 210 are soldered to one another. In the partially-high-density laminated substrate 100A in embodiment 2, the bumps 211 of the logic chip 210 are soldered to the lands 116 of the core portion 110A, pads 128a of the first wiring portions 120, and pads 136a of second wiring portions 130. As a result, as depicted in FIG. 8, the logic chip 210 is mounted on the core portion 110A, the first wiring portions 120, and the second wiring portions 130. The other basic structures of the partially-high-density laminated substrate 100A are the same as those of the partially-high-density laminated substrate 100 in embodiment 1, and detailed description of the same structures is omitted by denoting the same structures by the same reference numerals.

### Embodiment 3

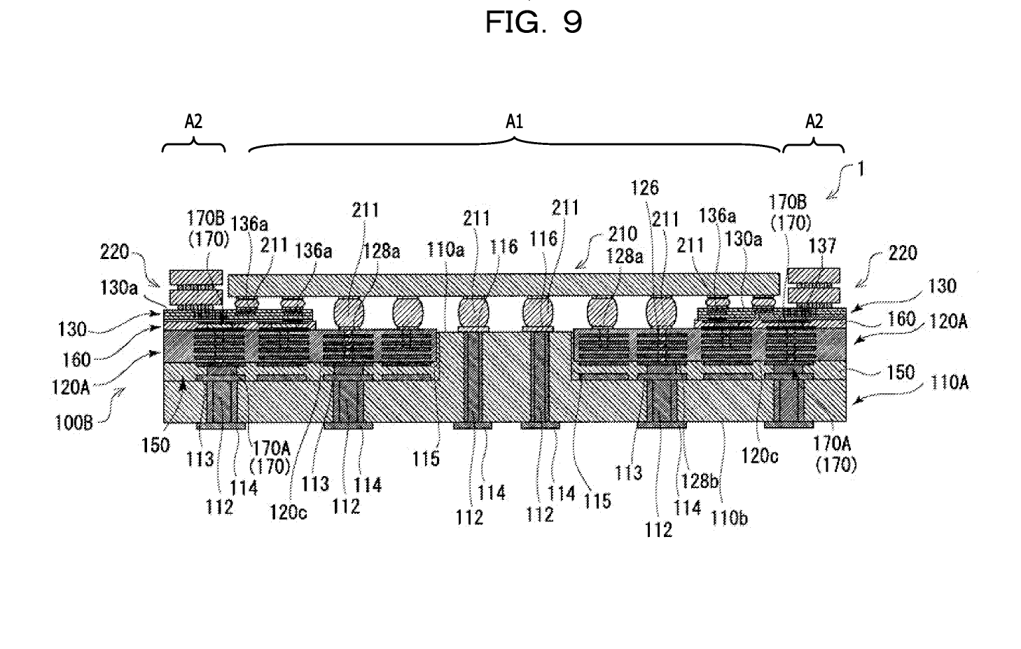

Next, a partially-high-density laminated substrate 100B in embodiment 3 is described. FIG. 9 is a cross-sectional view of the partially-high-density laminated substrate 100B in embodiment 3. In this section, differences from the partially-high-density laminated substrate 100A in embodiment 2 are mainly described. The partially-high-density laminated substrate 100B in embodiment 3 has a core portion 110A, first wiring portions 120A, and second wiring portions 130. The partially-high-density laminated substrate 100B in embodiment 3 is different from embodiments 1 and 2 in that, as depicted in FIG. 9, no recess portions which house the second wiring portions 130 are formed in the first wiring portions 120A. Moreover, second adhesive sheets 160 are disposed on covered upper surfaces 120b of the first wiring portions 120A such that exposed upper surfaces 120a thereof are exposed, and the second wiring portions 130 are bonded to the first wiring portions 120A via the second adhesive sheets 160.

Since no recess portions which house the second wiring portions 130 are formed in the first wiring portions 120A as described above, a level difference (step) is formed between each of the exposed upper surfaces 120a of the first wiring portions 120A and a corresponding one of the upper surfaces 130a of the second wiring portions 130. In view of this, in embodiment 3, unevenness (level difference) in a logic chip mounting region A1 of the partially-high-density laminated substrate 100B is reduced by the height of bumps 211 of a logic chip 210. In other words, it is possible to reduce the unevenness in the logic chip mounting region A1 by setting the bump height of the bumps 211 soldered to the pads 128a of the first wiring portions 120 higher than that of the bumps 211 soldered to the pads 136a of the second wiring portions 130. Due to this, the logic chip 210 may be preferably mounted even when unevenness is formed in the logic chip mounting region A1 of the partially-high-density laminated substrate 100B.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A laminated substrate comprising:
a core portion;
a first wiring portion configured to be stacked on the core portion and to include a first exposed surface formed by exposing at least part of a surface of the first wiring portion; and
a second wiring portion configured to be stacked on the first wiring portion, to include a second exposed surface formed by exposing at least part of a surface of the second wiring portion, and to have higher wiring density of conductor than the first wiring portion has,
wherein the first exposed surface and the second exposed surface are provided respectively with a first pad and a second pad which are to be connected to electrodes of one semiconductor chip to be mounted on both the first exposed surface and the second exposed surface.

2. The laminated substrate according to claim 1,
wherein the one semiconductor chip is mounted with the electrodes of the semiconductor chip being connected to the first pad and the second pad.

3. The laminated substrate according to claim 1,
wherein the core portion and the first wiring portion are connected to each other via a conductive material, and the first wiring portion and the second wiring portion are connected to each other via a conductive material.

4. The laminated substrate according to claim 3,
wherein at least part of the second wiring portion is housed in a recess portion provided in the first wiring portion.

5. A method for manufacturing a laminated substrate comprising:
stacking a first wiring portion on a core portion in such a way as to form a first exposed surface by exposing at least part of a surface of the first wiring portion;
stacking a second wiring portion on the first wiring portion in such a way as to form a second exposed surface by exposing at least part of a surface of the second wiring portion, the second wiring portion having higher wiring density of conductor than the first wiring portion has, and
forming a first pad and a second pad respectively on the first exposed surface and the second exposed surface, the first pad and the second pad formed to be connected to electrodes of one semiconductor chip to be mounted on both the first exposed surface and the second exposed surface.
